(19) United States
(12) Patent Application Publication
(10) Pub. No.: US 2025/0174571 A1
(43) Pub. Date: May 29, 2025

(54) INTERPOSER, METHOD OF FABRICATING THE SAME, AND SEMICONDUCTOR PACKAGE HAVING THE SAME

(71) Applicant: Samsung Electronics Co., Ltd., Suwon-si (KR)

(72) Inventors: Sungwoo Park, Suwon-si (KR); Junseop Byeon, Suwon-si (KR); Yongjae Kim, Suwon-si (KR); Hyeonjae Kim, Suwon-si (KR); Semin Oh, Suwon-si (KR)

(21) Appl. No.: 18/779,129

(22) Filed: Jul. 22, 2024

(30) Foreign Application Priority Data
Nov. 23, 2023 (KR) 10-2023-0164840

(51) Int. Cl. H01L 23/544; H01L 23/498

(52) U.S. Cl. CPC H01L 23/544; H01L 23/49811; H01L 2223/54426

(57) ABSTRACT

An interposer includes a base layer having a first surface and a second surface opposite to each other, a main region, and an alignment key region surrounding the main region, a wiring structure disposed on the first surface of the base layer and including a wiring conductive layer and an inter-wiring insulating layer surrounding the wiring conductive layer, an interposer protective layer on the second surface of the base layer, a rear wiring protective layer on an upper surface of the interposer protective layer, and an alignment electrode located in the alignment key region, passing through the base layer and the interposer protective layer, and inserted into the rear wiring protective layer. The alignment electrode is electrically insulated from the wiring conductive layer, and a vertical level of the upper surface of the interposer protective layer is constant from the main region to the alignment key region.

### CROSS-REFERENCE TO RELATED APPLICATION

This application is based on and claims priority under 35 U.S.C. § 119 to Korean Patent Application No. 10-2023-0164840, filed on Nov. 23, 2023, in the Korean Intellectual Property Office, the disclosure of which is incorporated by reference herein in its entirety.

### BACKGROUND

The inventive concept relates to an interposer electrically connecting a semiconductor chip to a main board, a method of fabricating the interposer, and a semiconductor package having the interposer.

As miniaturized, multi-functional, and high-performance electronic products are required, multi-functional, thinner, more integrated, higher performance, and faster semiconductor packages are also required. Accordingly, there is a growing demand for semiconductor packages for realizing high memory bandwidths. Since the memory bandwidth is proportional to the data transmission speed and number of data transmission lines, the memory bandwidth may be increased by increasing the memory operation speed or increasing the number of data transmission lines. Accordingly, semiconductor packages using interposers have been introduced in order to increase the number and density of connection bumps that are attached to connection pads of semiconductor chips.

### SUMMARY

The inventive concept provides an interposer having reduced manufacturing costs, a method of fabricating the interposer, and a semiconductor package including the interposer.

The inventive concept also provides an interposer facilitating alignment for a photolithography process, a method of fabricating the interposer, and a semiconductor package including the interposer.

The objects of the inventive concept are not limited to the object mentioned above, but other objects not described herein are clearly understood by those skilled in the art from the following description.

According to an aspect of the inventive concept, there is provided an interposer including a base layer having a first surface and a second surface opposite to each other, a main region, and an alignment key region surrounding the main region, a composite wiring layer disposed on the first surface of the base layer and including a wiring conductive layer and an inter-wiring insulating layer surrounding the wiring conductive layer, an interposer protective layer on the second surface of the base layer, a rear wiring protective layer on an upper surface of the interposer protective layer, and an alignment electrode located in the alignment key region passing through the base layer and the interposer protective layer, and a portion of the alignment electrode being inserted into the rear wiring protective layer. The alignment electrode is electrically insulated from the wiring conductive layer. A vertical level of the upper surface of the interposer protective layer is constant from the main region to the alignment key region.

According to another aspect of the inventive concept, there is provided an interposer including a base layer having a first surface and a second surface opposite to each other, a main region, and an alignment key region surrounding the main region, a composite wiring layer located in the main region and disposed on the first surface of the base layer, an interposer protective layer covering the second surface of the base layer, at least one interposer through-electrode located in the main region and passing through the base layer and the interposer protective layer, at least one alignment electrode located in the alignment key region and passing through the base layer and the interposer protective layer, an interposer pad covering a portion of the interposer through-electrode protruding from an upper surface of the interposer protective layer, an interposer connection terminal on the interposer pad, and a rear wiring protective layer covering a portion of the alignment electrode protruding from the upper surface of the interposer protective layer in a plan view.

According to another aspect of the inventive concept, there is provided a semiconductor package including an interposer including a base layer having a first surface and a second surface opposite to each other, a main region, and an alignment key region surrounding the main region, a wiring conductive layer on the first surface of the base layer, a plurality of bonding pads arranged in the main region and connected to the wiring conductive layer, a rear wiring protective layer above the second surface of the base layer, an interposer protective layer between the base layer and the rear wiring protective layer, at least one interposer through-electrode located in the main region and passing through the base layer and the interposer protective layer, at least one alignment electrode located in the alignment key region passing through the base layer and the interposer protective layer, and a portion of the alignment electrode being inserted into the rear wiring protective layer, and an interposer pad between the interposer through-electrode and the rear wiring protective layer, a first semiconductor chip disposed on the first surface of the base layer, electrically connected to corresponding ones of the plurality of bonding pads, a second semiconductor chip spaced apart from the first semiconductor chip in a horizontal direction and disposed on the first surface of the base layer and electrically connected to corresponding ones of the plurality of bonding pads. The alignment electrode is electrically insulated from the interposer pad, the first semiconductor chip and the second semiconductor chip.

### BRIEF DESCRIPTION OF THE DRAWINGS

Embodiments will be more clearly understood from the following detailed description taken in conjunction with the accompanying drawings in which:

FIG. 1 is a plan view showing an interposer according to an embodiment;

FIG. 2 is a cross-sectional view of the interposer taken along lines A-A′ and B-B′ of FIG. 1;

FIG. 3A is an enlarged cross-sectional view of region PP1 of FIG. 2, showing a portion of the interposer according to an embodiment;

FIG. 3B is an enlarged cross-sectional view of region PP2 of FIG. 2, showing a portion of the interposer according to an embodiment;

FIG. 4 is an enlarged cross-sectional view of region PP2 of FIG. 2, showing a portion of the interposer according to an embodiment;

FIG. 5A is an enlarged cross-sectional view of region PP1 of FIG. 2, showing a portion of the interposer according to an embodiment;

FIG. 5B is an enlarged cross-sectional view of region PP2 of FIG. 2, showing a portion of the interposer according to an embodiment;

FIGS. 6A to 12B are cross-sectional views sequentially showing a method of fabricating an interposer, according to an embodiment; and

FIG. 13 is a cross-sectional view showing a semiconductor package including an interposer according to embodiments.

### DETAILED DESCRIPTION OF THE EMBODIMENTS

Hereinafter, embodiments are described in detail with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

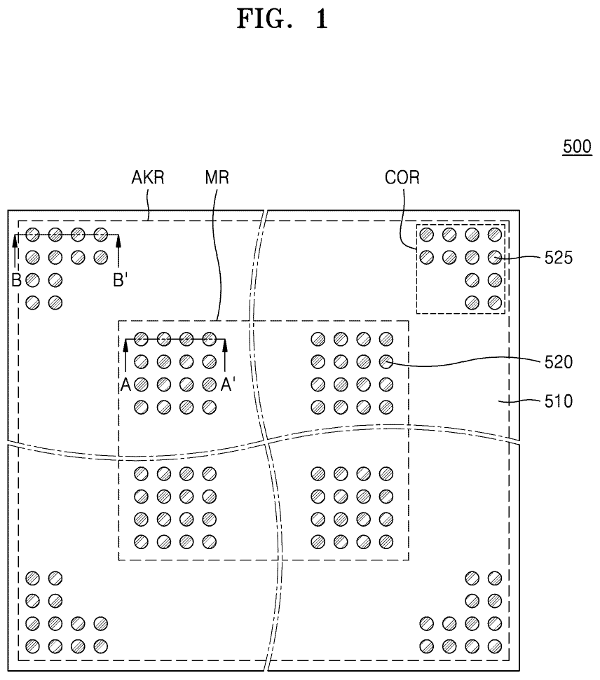

FIG. 1 is a plan view showing an interposer 500 according to an embodiment.

Referring to FIG. 1, the interposer 500 may include a main region MR and an alignment key region AKR. The main region MR may include a region in which an interposer through-electrode 520 is located. For example, in a plan view, the main region MR may be located at a center of the interposer 500. A plurality of interposer through-electrodes 520 may be provided. In this specification, the interposer 500 is described as including the main region MR and the alignment key region AKR, but a base layer 510 may also be expressed as including the main region MR and the alignment key region AKR.

The alignment key region AKR may include a region in which an alignment electrode 525 is located. For example, in a plan view, the alignment key region AKR may be an edge region of the interposer 500. The alignment key region AKR may surround the main region MR in a plan view.

It will be understood that when the alignment key region AKR is referred to as “surround” (or any form of the word “surround” e.g., “surrounding”) the main region MR, it does not necessarily mean that alignment key (i.e., a plurality of alignment electrodes which will be described later) itself entirely enclose the main region MR. It should be appreciated that the alignment key (or keys) may be located in a portion of the alignment key region AKR as shown in the figures the alignment key may be located adjacent to a portion of the main region MR. For example, the alignment key region AKR may include a corner region COR. In a plan view, the corner region COR may be located at each of four corners of the interposer 500. For example, the alignment electrode 525 may be located in the corner region COR of the interposer 500. The phrase “plan view” is used when an object portion is viewed in a vertical direction from above, and the phrase “cross-section” means when a cross-section taken by vertically cutting an object portion is viewed from the side. Throughout the specification and claims, the term “vertical” or “vertically”, refers to the direction perpendicular to two substantially flat surfaces of the interposer, and the term “horizontal” or “horizontally” refers to any direction that is parallel to the two substantially flat surfaces of the interposer.

A plurality of alignment electrodes 525 may be provided. The plurality of alignment electrodes 525 may be two-dimensionally arranged in the alignment key region AKR. Specifically, in a plan view, the plurality of alignment electrodes 525 may be arranged in a certain pattern. In a plan view, the plurality of alignment electrodes 525 may be arranged in a certain pattern in each of the plurality of corner regions COR. In a plan view, the pattern of the plurality of two-dimensionally arranged alignment electrodes 525 may be different from the pattern of the plurality of two-dimensionally arranged interposer through-electrodes 520. For example, the plurality of alignment electrodes 525 is arranged two-dimensionally in a plan view to form a first pattern, and the plurality of interposer through-electrodes 520 is arranged two-dimensionally in a plan view to form a second pattern. The first and second patterns are different from each other.

For example, in a plan view, the plurality of interposer through-electrodes 520 may be arranged side by side in a first horizontal direction and a second horizontal direction intersecting with the first horizontal direction. On the other hand, in a plan view, the plurality of alignment electrodes 525 may be arranged in an “L” shape. However, this only corresponds to one embodiment. In a plan view, the plurality of alignment electrodes 525 may be two-dimensionally arranged in a polygonal shape, circular shape, oval shape, ring shape, or diamond shape.

The plurality of alignment electrodes 525 may form a specific planar shape and perform a function of an alignment key. The alignment key may be configured to be used as an indicator used to ensure the function of aligning a photo mask during a photolithography process in a subsequent process.

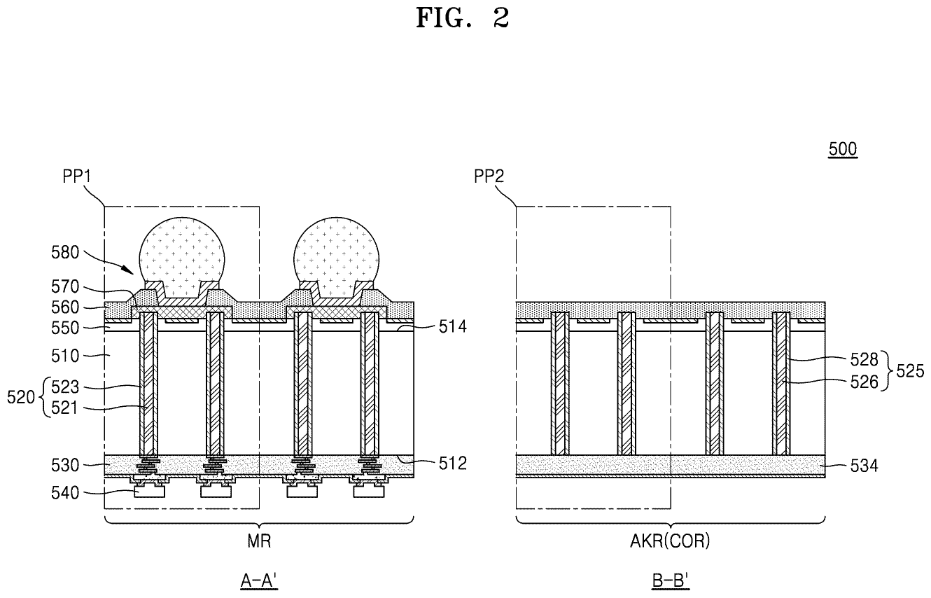

FIG. 2 is a cross-sectional view of an interposer 500 taken along lines A-A′ and B-B′ of FIG. 1. It should be noted that items described in the singular herein, may be provided in plural, as can be seen in the various figures from the context in which they are described.

Referring to FIG. 2, the interposer 500 may include a base layer 510, an interposer through-electrode 520 and an alignment electrode 525 connecting a first surface 512 and a second surface 514 of the base layer 510, a wiring structure 530 disposed on the first surface 512 of the base layer 510, a bonding pad 540 disposed above the first surface 512 of the base layer 510 and electrically connected to the wiring structure 530, an interposer protective layer 550 covering the second surface 514 of the base layer 510, an interposer pad 570 disposed on the interposer protective layer 550, and a rear wiring protective layer 560 that exposes a portion of the interposer pad 570 and covers the interposer protective layer 550 and the interposer pad 570. The interposer 500 may further include an interposer connection terminal 580 attached to the interposer pad 570.

The base layer 510 may include semiconductor material, glass, ceramic, or plastic material. For example, the base layer 510 may include silicon. In some embodiments, the base layer 510 may be formed from a silicon semiconductor substrate. It will be understood that when an element is referred to as being “connected” (or any form of the word “connected” e.g., “connect,” “connecting”), it can be directly connected to another element or intervening elements may be present. It also may be electrically and/or physically connected to the other element. As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component.

The interposer through-electrode 520 may be located in the main region MR of FIG. 1. The interposer through-electrode 520 may include a first conductive plug 521 passing through the base layer 510 and a first via insulating film 523 surrounding the first conductive plug 521. The interposer through-electrode 520 may further include a conductive barrier film between the first conductive plug 521 and the first via insulating film 523.

The alignment electrode 525 may be located in the alignment key region AKR of FIG. 1. The alignment electrode 525 may include a second conductive plug 526 passing through the base layer 510 and a second via insulating film 528 surrounding the second conductive plug 526. The alignment electrode 525 may further include a conductive barrier film between the second conductive plug 526 and the second via insulating film 528.

The first conductive plug 521 and the second conductive plug 526 may each include titanium (Ti), tungsten (W), copper (Cu), aluminum (Al), cobalt (Co), or a combination thereof. The conductive barrier film may include metal or conductive metal nitride. The conductive barrier film may include, for example, titanium (Ti), titanium nitride (TiN), tantalum (Ta), tantalum nitride (TaN), or a combination thereof. The first conductive plug 521 and the second conductive plug 526 may each have a cylindrical shape. The first via insulating film 523 may prevent the base layer 510 from being in direct contact with the first conductive plug 521. The second via insulating film 528 may prevent the base layer 510 from being in direct contact with the second conductive plug 526. The first via insulating film 523 and the second via insulating film 528 may each include an oxide film, nitride film, carbide film, polymer, or a combination thereof.

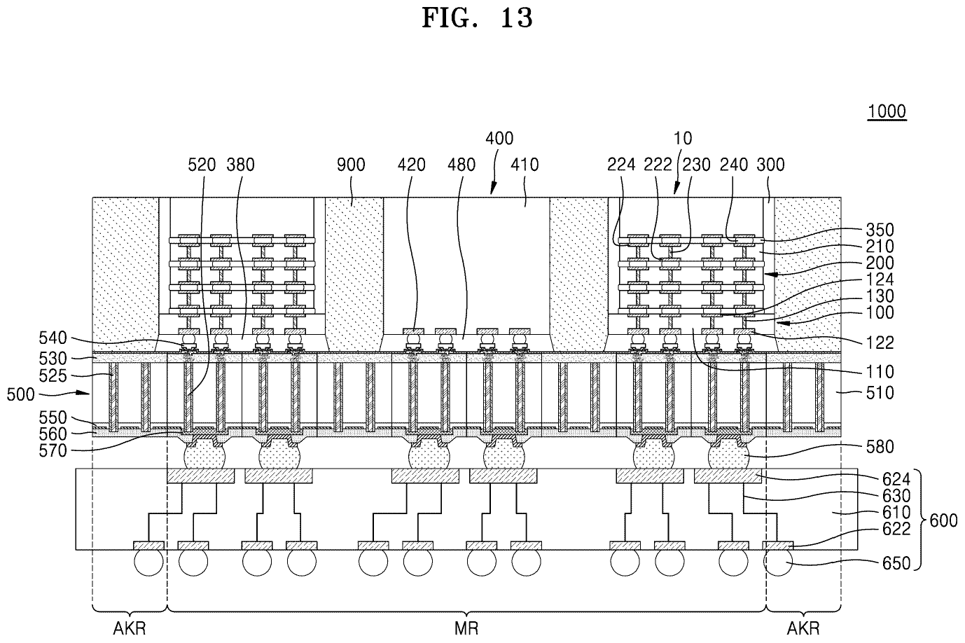

FIG. 1 shows that the first surface 512 and the second surface 514 of the base layer 510 are provided in lower and upper sides of the base layer 510, respectively. However, based on a semiconductor package 1000 having the interposer 500 shown in FIG. 13, the first surface 512 and the second surface 514 of the base layer 510 may be referred to as an upper surface and a lower surface, respectively. That is, for the interposer 500 shown in FIG. 2 and the interposer 500 of the semiconductor package 1000 shown in FIG. 13, upper and lower sides thereof are turned over each other. In other words, the interposer 500 shown in FIG. 2 is turned over in the semiconductor package 1000 shown in FIG. 13. Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “upper” can encompass both an orientation of upper and lower. The device may be otherwise oriented (rotated 90 degrees or at other orientations) and the spatially relative descriptors used herein interpreted accordingly.

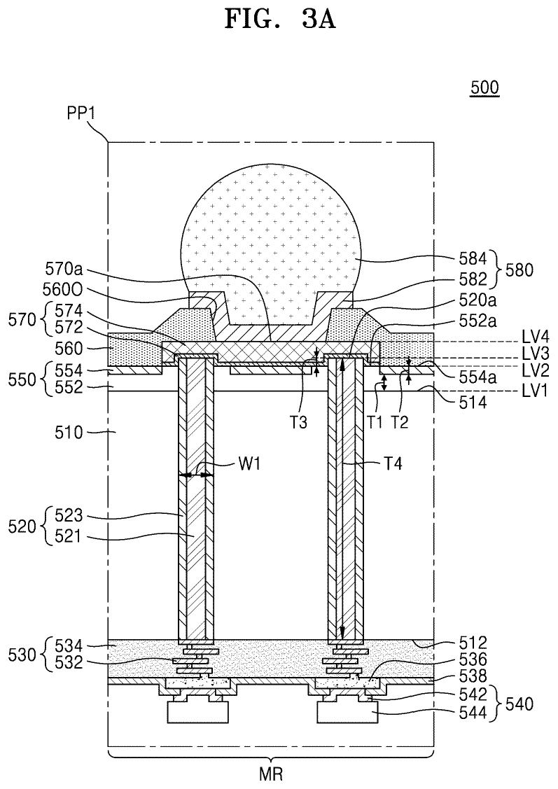

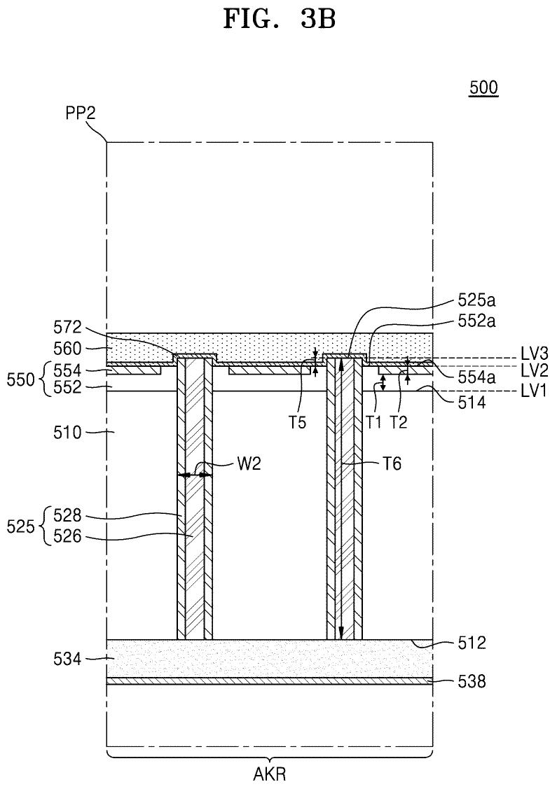

FIG. 3A is an enlarged cross-sectional view of region PP1 of FIG. 2, showing a portion of the interposer 500 according to an embodiment. FIG. 3B is an enlarged cross-sectional view of region PP2 of FIG. 2, showing a portion of the interposer 500 according to an embodiment.

Hereinafter, features described with reference to FIG. 3A may be only to describe the main region MR of the interposer 500, unless specified otherwise. The alignment key region AKR of the interposer 500 is described below with reference to FIG. 3B.

Referring to FIG. 3A, in the main region MR, the interposer 500 may include the base layer 510, the interposer through-electrode 520, the wiring structure 530, the bonding pad 540, the interposer protective layer 550, the interposer pad 570, and the rear wiring protective layer 560.

The features of the base layer 510 may be the same as those of the base layer 510 described with reference to FIG. 2, so that repeated elements will be briefly explained or omitted.

The wiring structure 530 (also described as “composite wiring layer”) includes a wiring conductive layer 532 and an inter-wiring insulating layer 534 surrounding the wiring conductive layer 532. The wiring conductive layer 532 may electrically connect the interposer through-electrode 520 and the bonding pad 540 to each other. As used herein throughout the specification and claims, the term “surround” (or “surrounding”) does not necessarily mean “entirely surround,” unless the context clearly indicates otherwise. For example, the inter-wiring insulating layer 534 may partially surround (such as “cover”) the wiring conductive layer 532, thereby exposing a portion of the wiring conductive layer 532 and ensuring the electrical connection to the interposer through-electrode 520 and the bonding pad 540.

The wiring conductive layer 532 may include a metal material, such as aluminum, copper, or tungsten. The inter-wiring insulating layer 534 may include silicon oxide. In some embodiments, the inter-wiring insulating layer 534 may include tetraethyl orthosilicate (TEOS). In some embodiments, the inter-wiring insulating layer 534 may include an insulating material having lower permittivity than silicon oxide, for example, an ultra-low k (ULK) film having an ultra-low dielectric constant K of about 2.2 to about 2.4.

A plurality of wiring conductive layers 532 may be provided. The plurality of wiring conductive layers 532 may include a plurality of subsidiary layers stacked in the vertical direction. Each of the subsidiary layers may include a plurality of wiring patterns. The plurality of wiring conductive layers 532 may further include a plurality of wiring vias. The wiring vias may connect the wiring patterns each of which is arranged on different subsidiary layers respectively. The subsidiary layer refers to a portion of the wiring conductive layers 532 in which an electrical path or electrical paths are extending on a plane. It will be understood that when one of the subsidiary layers is referred to as being “different” from another subsidiary layer, the two subsidiary layers are arranged on two deferent planes at different vertical levels respectively.

A pad wiring pattern 536 connected to the wiring conductive layer 532 and disposed on the composite wiring layer 530 (i.e., wiring structure) may be located between the wiring conductive layer 532 and the bonding pad 540. For example, the pad wiring pattern 536 may include copper, nickel, or a copper alloy. A front wiring protective layer 538 may cover the wiring structure 530 and the pad wiring pattern 536 while exposing a portion of the pad wiring pattern 536. The front wiring protective layer 538 may include epoxy or polyimide.

The bonding pad 540 may include a front under bump metallurgy (UBM) layer 542 in contact with the pad wiring pattern 536 and a chip connection terminal 544 in contact with the front UBM layer 542. The bonding pad 540 may include a conductive material, such as copper (Cu), aluminum (Al), silver (Ag), tin (Sn), gold (Au), or solder, but the embodiment is not limited thereto. The term “contact” (or any form of the word “contact” e.g., “contacting,” “contacts,” or “in contact with”) as used herein, refers to a direct connection (i.e., touching) unless the context clearly indicates otherwise. The term “directly” may be used herein to emphasize this meaning, unless the context or other statements indicate otherwise.

The interposer protective layer 550 may include a lower interposer protective layer 552 covering the second surface 514 of the base layer 510 and an upper interposer protective layer 554 covering the lower interposer protective layer 552. The lower interposer protective layer 552 may cover a portion of a sidewall of the interposer through-electrode 520 that protrudes from the second surface 514 of the base layer 510. The upper interposer protective layer 554 may be spaced apart from the interposer through-electrode 520.

The interposer protective layer 550 may include an inorganic material. For example, the interposer protective layer 550 may include silicon oxide, silicon nitride, or a stacked structure of silicon oxide and silicon nitride. For example, the lower interposer protective layer 552 may include oxide, and the upper interposer protective layer 554 may include nitride. In some embodiments, the lower interposer protective layer 552 may include silicon oxide, and the upper interposer protective layer 554 may include silicon nitride. Alternatively, the interposer protective layer 550 may include or be formed of a photo imageable dielectric (PID).

The lower interposer protective layer 552 and the upper interposer protective layer 554 may have a first thickness T1 and a second thickness T2, respectively, as thicknesses thereof. For example, in a portion in which the lower interposer protective layer 552 and the upper interposer protective layer 554 vertically overlap each other, the lower interposer protective layer 552 and the upper interposer protective layer 554 may have the first thickness T1 and the second thickness T2, respectively. Each of the first and second thicknesses T1 and T2 is substantially constant (i.e., uniform) in a horizontal direction in the vertically overlapped portion. In some embodiments, the first thickness T1 of the lower interposer protective layer 552 may be greater than the second thickness T2 of the upper interposer protective layer 554. For example, the second thickness T2 may be about 0.5 μm to about 1.5 μm, and the first thickness T1 may be greater than the second thickness T2 but not more than 2.5 μm.

The lower surface of the lower interposer protective layer 552 may be at a first vertical level LV1 and an upper surface 554a of the upper interposer protective layer 554 may be at a second vertical level LV2 that is higher than the first vertical level LV1. The second surface 514 of the base layer 510 may be at the first vertical level LV1. An uppermost surface 552a of the lower interposer protective layer 552 may be at the second vertical level LV2.

Both the uppermost surface 552a of the lower interposer protective layer 552 and the upper surface 554a of the upper interposer protective layer 554 (hereinafter, referred to as the upper surfaces 552a and 554a of the interposer protective layer 550) may be flat. The upper surfaces 552a and 554a of the interposer protective layer 550 may extend flatly in a horizontal direction. The uppermost surface 552a of the lower interposer protective layer 552 and the upper surface 554a of the upper interposer protective layer 554 may be coplanar with each other. The upper surfaces 552a and 554a of the interposer protective layer 550 may extend flatly in a horizontal direction throughout the main region MR and the alignment key region AKR. In other words, the vertical levels of the upper surfaces 552a and 554a of the interposer protective layer 550 may be constant from the main region MR to the alignment key region AKR. That is, the second vertical level LV2 may be constant in the main region MR and the alignment key region AKR. Terms such as “constant,” “flat,” “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially constant,” “substantially the same,” “substantially equal,” or “substantially planar,” may be exactly the same, equal, or planar, or may be the same, equal, or planar within acceptable variations that may occur, for example, due to manufacturing processes.

The interposer pad 570 may include a seed layer 572 and a conductive pad layer 574. The seed layer 572 may cover the upper surfaces 552a and 554a of the interposer protective layer 550. The seed layer 572 may cover the upper surface and side surface of a portion of the interposer through-electrode 520 that protrudes from the upper surfaces 552a and 554a of the interposer protective layer 550. The conductive pad layer 574 may be disposed on the seed layer 572. A plurality of interposer pads 570 may be provided.

The seed layer 572 may include titanium (Ti), tungsten (W), copper (Cu), aluminum (Al), cobalt (Co), or a combination thereof.

The interposer pad 570 may be located in the main region MR. The seed layer 572 may conformally cover the upper surface and side surface of the portion of the interposer through-electrode 520 that protrudes from the upper surfaces 552a and 554a of the interposer protective layer 550. The term “conformally” describes a coating material in which angles of the underlying material are preserved by the conformal material. An upper surface 570a of the interposer pad 570 may be at a fourth vertical level LV4. The fourth vertical level LV4 may be higher than the first to third vertical levels LV1 to LV3. The lower surface of the interposer pad 570 may be at the second vertical level LV2.

FIG. 3A illustrates that the uppermost surface 552a of the lower interposer protective layer 552, the upper surface 554a of the upper interposer protective layer 554, the upper surface 570a of the interposer pad 570, and an upper surface 520a of the interposer through-electrode 520 are on the upper side of the interposer 500. However, based on the semiconductor package 1000 having the interposer 500 shown in FIG. 13, the uppermost surface 552a of the lower interposer protective layer 552, the upper surface 554a of the upper interposer protective layer 554, the upper surface 570a of the interposer pad 570, and the upper surface 520a of the interposer through-electrode 520 may be on the lower side of the semiconductor package 1000. This is because, for the interposer 500 shown in FIG. 3A and the interposer 500 of the semiconductor package 1000 shown in FIG. 13, upper and lower sides thereof are turned over each other. In other words, the interposer 500 shown in FIG. 3A is turned over in the semiconductor package 1000 shown in FIG. 13.

The interposer through-electrode 520 may pass through the base layer 510 and the interposer protective layer 550. The interposer through-electrode 520 may extend into the interposer pad 570. For example, a portion of the interposer through-electrode 520 may be covered by a recessed portion of the interposer pad 570. Therefore, at least the portion of the interposer through-electrode 520 may be partially inserted into the interposer pad 570. As used herein, an element described as being “partially inserted into” another element is configured such that the element does not pass though the other element.

The upper surface 520a of the interposer through-electrode 520 may be at the third vertical level LV3, which is higher than the second vertical level LV2. The vertical level of the upper surface 520a of the interposer through-electrode 520 may be higher than the vertical level of the upper surfaces 552a and 554a of the interposer protective layer 550. The interposer through-electrode 520 may have a portion protruding from the upper surfaces 552a and 554a of the interposer protective layer 550.

The interposer through-electrode 520 may have a first width W1 in a horizontal direction. The first width W1 of the interposer through-electrode 520 may be defined as a width in the horizontal direction. The first width W1 may be about 0.5 μm to about 20 μm. The portion of the interposer through-electrode 520, protruding from the upper surfaces 552a and 554a of the interposer protective layer 550, may have a third thickness T3. The third thickness T3 of the protruding portion of the interposer through-electrode 520 may be greater than 0 μm but not more than 1.5 μm. Also, the third thickness T3 may be about 1/30 to about 1/10 of the first width W1. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

For example, the third thicknesses T3 of the plurality of interposer through-electrodes 520 may be different from each other. That is, portions of the plurality of interposer through-electrodes 520, protruding from the upper surfaces 552a and 554a of the interposer protective layer 550, may have different thicknesses. The difference between (i.e., variation range of) the thicknesses of the portions of the plurality of interposer through-electrodes 520, protruding from the upper surfaces 552a and 554a of the interposer protective layer 550, may be within 0.1 μm. The difference between the third thicknesses T3 of the plurality of interposer through-electrodes 520 may be within 0.1 μm.

The total vertical height of the interposer through-electrode 520 may be a fourth thickness T4. The fourth thickness T4 of the interposer through-electrode 520 may be about 10 μm to about 120 μm.

Another portion of the lower surface of the interposer pad 570, other than the portion thereof in contact with the interposer through-electrode 520, may be in contact with the interposer protective layer 550. The lower surface of the interposer pad 570 may be completely covered by the interposer through-electrode 520 and the interposer protective layer 550. A portion of the interposer through-electrode 520 above the first vertical level LV1, at which the upper surface of the base layer 510 is located, may be surrounded by the interposer pad 570.

The rear wiring protective layer 560 may cover a portion of the interposer pad 570 and may expose the other portion of the interposer pad 570. The rear wiring protective layer 560 may have a terminal opening 5600, through which a portion of the interposer pad 570 is exposed, and cover the interposer protective layer 550 and the other portion of the interposer pad 570. For example, the rear wiring protective layer 560 may cover a portion of the interposer pad 570 and may expose the other portion of the interposer pad 570. The rear wiring protective layer 560 may have a terminal opening 5600, through which the interposer pad 570 is exposed. The rear wiring protective layer 560 may cover the interposer protective layer 550.

The rear wiring protective layer 560 may completely cover the side surface of the interposer pad 570 and cover at least a portion of the upper surface 570a of the interposer pad 570. The rear wiring protective layer 560 may have the terminal opening 5600 that does not cover but exposes the other portion of the upper surface 570a of the interposer pad 570. The rear wiring protective layer 560 may be spaced apart from the interposer through-electrode 520.

The rear wiring protective layer 560 may include an organic material. For example, the rear wiring protective layer 560 may include a polymer material. In some embodiments, the rear wiring protective layer 560 may be formed from the PID such as polyimide. Also, in some embodiments, the rear wiring protective layer 560 may include a low-k dielectric material, such as silicon oxide, silicon nitride, and silicon oxynitride.

The interposer connection terminal 580 may include a rear UBM layer 582 on the interposer pad 570 and an interposer conductive cap 584 on the rear UBM layer 582.

The rear UBM layer 582 may cover a portion of the upper surface 570a of the interposer pad 570, which is exposed via the terminal opening 5600. The rear UBM layer 582 may cover a portion of the rear wiring protective layer 560, which is adjacent to the exposed portion of the upper surface 570a of the interposer pad 570. The rear UBM layer 582 may have a concave upper surface corresponding to the terminal opening 5600.

The interposer conductive cap 584 may cover all or most of the upper surface of the rear UBM layer 582. In some embodiments, the interposer connection terminal 580 may include a conductive material, such as copper (Cu), aluminum (Al), silver (Ag), tin (Sn), gold (Au), or solder, but the embodiment is not limited thereto. The interposer connection terminal 580 may be formed as a single layer or multi layers. In some embodiments, the interposer conductive cap 584 may include SnAg. The interposer conductive cap 584 may be a gold stud bump or a solder ball.

FIG. 3B is an enlarged cross-sectional view of region PP2 of FIG. 2, showing a portion of the interposer 500 according to an embodiment.

Hereinafter, features described with reference to FIG. 3B may be only to describe the alignment key region AKR of the interposer 500.

Referring to FIG. 3B, in the alignment key region AKR, the interposer 500 may include the base layer 510, the alignment electrode 525, the inter-wiring insulating layer 534, the interposer protective layer 550, and the rear wiring protective layer 560.

The features of the base layer 510 may be the same as those of the base layer 510 described with reference to FIG. 2, so that repeated elements will be briefly explained or omitted. The base layer 510 may be located throughout the main region MR and the alignment key region AKR.

The inter-wiring insulating layer 534 may be extending from the main region MR to the alignment key region AKR. The inter-wiring insulating layer 534 may include silicon oxide. In some embodiments, the inter-wiring insulating layer 534 may include TEOS. In some embodiments, the inter-wiring insulating layer 534 may include an insulating material having lower permittivity than silicon oxide, for example, a ULK film having an ultra-low dielectric constant K of about 2.2 to about 2.4.

Unlike the main region MR, the alignment key region AKR may not include the wiring conductive layer 532 (FIG. 3A), the pad wiring pattern 536, and the bonding pad 540.

The front wiring protective layer 538 may cover the lower surface of the inter-wiring insulating layer 534. The front wiring protective layer 538 may be extending from the main region MR to the alignment key region AKR. The front wiring protective layer 538 may include epoxy or polyimide.

The interposer protective layer 550 may include a lower interposer protective layer 552 covering the second surface 514 of the base layer 510 and an upper interposer protective layer 554 covering the lower interposer protective layer 552. The interposer protective layer 550 may be extending from the main region MR to the alignment key region AKR. The lower interposer protective layer 552 may cover a portion of a sidewall of the alignment electrode 525 that protrudes from the second surface 514 of the base layer 510. The upper interposer protective layer 554 may be spaced apart from the alignment electrode 525.

The interposer protective layer 550 may include an inorganic material. For example, the interposer protective layer 550 may include silicon oxide, silicon nitride, or a stacked structure of silicon oxide and silicon nitride. For example, the lower interposer protective layer 552 may include oxide and the upper interposer protective layer 554 may include nitride. In some embodiments, the lower interposer protective layer 552 may include silicon oxide and the upper interposer protective layer 554 may include silicon nitride. Alternatively, the interposer protective layer 550 may include or be formed of a PID.

The lower interposer protective layer 552 and the upper interposer protective layer 554 may have a first thickness T1 and a second thickness T2, respectively, as thicknesses thereof. For example, in a portion in which the lower interposer protective layer 552 and the upper interposer protective layer 554 vertically overlap each other, the lower interposer protective layer 552 and the upper interposer protective layer 554 may have the first thickness T1 and the second thickness T2, respectively. Each of the first and second thicknesses T1 and T2 is substantially constant (i.e., uniform) in a horizontal direction in the vertically overlapped portion. In some embodiments, the first thickness T1 of the lower interposer protective layer 552 may be greater than the second thickness T2 of the upper interposer protective layer 554. For example, the second thickness T2 may be about 0.5 μm to about 1.5 μm, and the first thickness T1 may be greater than the second thickness T2 but not more than 2.5 μm.

The lower surface of the lower interposer protective layer 552 may be at a first vertical level LV1 and an upper surface 554a of the upper interposer protective layer 554 may be at a second vertical level LV2 that is higher than the first vertical level LV1. The second surface 514 of the base layer 510 may be at the first vertical level LV1. An uppermost surface 552a of the lower interposer protective layer 552 may be at the second vertical level LV2.

The upper surfaces 552a and 554a of the interposer protective layer 550 may be flat. The upper surfaces 552a and 554a of the interposer protective layer 550 may extend flatly in a horizontal direction. The uppermost surface 552a of the lower interposer protective layer 552 and the upper surface 554a of the upper interposer protective layer 554 may be coplanar with each other.

The seed layer 572 may cover the upper surfaces 552a and 554a of the interposer protective layer 550. Unlike in FIG. 3A, the conductive pad layer 574 may not be provided in the alignment key region AKR. The seed layer 572 may cover the upper surface and side surface of a portion of the alignment electrode 525 that protrudes from the upper surfaces 552a and 554a of the interposer protective layer 550. The seed layer 572 may conformally cover the upper surface and side surface of the portion of the alignment electrodes 525 that protrudes from the upper surfaces 552a and 554a of the interposer protective layer 550. The seed layer 572 may extend in the horizontal direction and cover the upper surfaces 552a and 554a of the interposer protective layer 550.

The seed layer 572 may include titanium (Ti), tungsten (W), copper (Cu), aluminum (Al), cobalt (Co), or a combination thereof.

FIG. 3B illustrates that the uppermost surface 552a of the lower interposer protective layer 552, the upper surface 554a of the upper interposer protective layer 554, and an upper surface 525a of the alignment electrodes 525 are on the upper side of the interposer 500. However, based on the semiconductor package 1000 having the interposer 500 shown in FIG. 13, the uppermost surface 552a of the lower interposer protective layer 552, the upper surface 554a of the upper interposer protective layer 554, and the upper surface 525a of the alignment electrode 525 may be on the lower side of the semiconductor package 1000. This is because, for the interposer 500 shown in FIG. 3B and the interposer 500 of the semiconductor package 1000 shown in FIG. 13, upper and lower sides thereof are turned over each other. In other words, the interposer 500 shown in FIG. 3B is turned over in the semiconductor package 1000 shown in FIG. 13.

The alignment electrode 525 may pass through the base layer 510 and the interposer protective layer 550. The alignment electrode 525 may extend into the rear wiring protective layer 560. For example, the protruded portion of the alignment electrode 525 beyond the upper surfaces 552a and 554a of the interposer protective layer 550 in the vertical direction, may be covered by a recessed portion of the rear wiring protective layer 560. Therefore, at least a portion of the alignment electrode 525 may partially inserted into the rear wiring protective layer 560.

The upper surface 525a of the alignment electrode 525 may be at the third vertical level LV3, which is higher than the second vertical level LV2. The vertical level of the upper surface 525a of the alignment electrode 525 may be higher than the vertical level of the upper surfaces 552a and 554a of the interposer protective layer 550. The alignment electrode 525 may have a portion protruding from the upper surfaces 552a and 554a of the interposer protective layer 550.

The alignment electrode 525 may have a second width W2 in a horizontal direction. The second width W2 of the alignment electrode 525 may be defined as a width in the horizontal direction. The second width W2 may be about 0.5 μm to about 20 μm. The portion of the alignment electrode 525, protruding from the upper surfaces 552a and 554a of the interposer protective layer 550, may have a fifth thickness T5. The fifth thickness T5 of the protruding portion of the alignment electrode 525 may be greater than 0 μm but not more than 1.5 μm. Also, the fifth thickness T5 may be about 1/30 to about 1/10 of the second width W2.

When the fifth thickness T5 is less than 1/30 of the second width W2, the alignment electrode 525 may not be clearly distinguished from other components of the interposer 500 on a planar image of the interposer 500. Therefore, the alignment electrode 525 may not properly perform the function of the alignment key in the subsequent photolithography process. On the other hand, when the fifth thickness T5 is greater than 1/10 of the second width W2, a dimple may be formed in the alignment electrode 525. The dimple may include a recess that is vertically recessed downward from the upper surface 525a of the alignment electrode 525. The dimple may adversely affect alignment operations in subsequent photolithography processes. Therefore, when the fifth thickness T5 is about 1/30 to about 1/10 of the second width W2, subsequent photolithography processes may be easily performed.

For example, the fifth thicknesses T5 of the plurality of alignment electrodes 525 may be different from each other. That is, portions of the plurality of alignment electrodes 525, protruding from the upper surfaces 552a and 554a of the interposer protective layer 550, may have different thicknesses. The difference between (i.e., variation range of) the thicknesses of the portions of the plurality of alignment electrodes 525, protruding from the upper surfaces 552a and 554a of the interposer protective layer 550, may be within 0.1 μm. The difference between the fifth thicknesses T5 of the plurality of alignment electrodes 525 may be within 0.1 μm.

The total vertical height of the alignment electrode 525 may be a sixth thickness T6. The sixth thickness T6 of the alignment electrode 525 may be about 10 μm to about 120 μm.

The alignment electrode 525 may be electrically insulated from the interposer through-electrode 520, the wiring conductive layer 532, the bonding pad 540, and the interposer pad 570. The alignment electrode 525 may include a dummy electrode. For example, the alignment electrode 525 may not have any function other than the function of the alignment key.

The rear wiring protective layer 560 may cover the seed layer 572. Unlike in FIG. 3A, the rear wiring protective layer 560 may not have a terminal opening 5600 in the alignment key region AKR. The rear wiring protective layer 560 may extend in the horizontal direction and have a flat upper surface. The recessed portion of the rear wiring protective layer 560 may cover (i.e., overlap) the upper surface of the alignment electrode 525 in a plan view, and a diameter of the recessed portion in a plan view is substantially same as a sum of the second width W2 and a thickness of the seed layer 572. The recessed portion of the rear wiring protective layer 560 may cover the side surface of the portion of an alignment electrode 525

The rear wiring protective layer 560 may include an organic material. For example, the rear wiring protective layer 560 may include a polymer material. In some embodiments, the rear wiring protective layer 560 may be formed from the PID such as polyimide. Also, in some embodiments, the rear wiring protective layer 560 may include a low-k dielectric material, such as silicon oxide, silicon nitride, and silicon oxynitride.

Unlike in FIG. 3A, the interposer connection terminal 580 may not be provided in the alignment key region AKR.

According to an aspect of the inventive concept, the plurality of alignment electrodes 525 may be arranged in a certain pattern in the alignment key region AKR, which is different from the main region MR. Consequently, the plurality of alignment electrodes 525 may perform the function of the alignment key when forming the interposer pad 570 in the main region MR. Here, during the process of fabricating the interposer 500, the plurality of alignment electrodes 525 may be formed simultaneously with the plurality of interposer through-electrodes 520. Therefore, there is no need to perform an additional process to form a component that performs the function of the alignment key. For the above reasons, the cost required for the process of fabricating the interposer 500 may be reduced.

If the third thickness T3 of the protruding portion of the interposer through-electrode 520 and the fifth thickness T5 of the protruding portion of the alignment electrode 525 are each greater than 1.5 μm, dimples may be formed in the interposer through-electrode 520 and the alignment electrode 525. The dimples may include recesses that are vertically recessed downward from the upper surface 520a of the interposer through-electrode 520 and the upper surface 525a of the alignment electrode 525.

According to an aspect of the inventive concept, the third thickness T3 and the fifth thickness T5 may each be greater than 0 μm but not more than 1.5 μm. Accordingly, under the thickness conditions described above, the dimples may not appear on the upper surface 520a of the interposer through-electrode 520 and the upper surface 525a of the alignment electrode 525. For the above reasons, the alignment for subsequent photolithography processes may be easily performed.

If the variation range of the thicknesses of the portions of the plurality of alignment electrodes 525, protruding from the upper surfaces 552a and 554a of the interposer protective layer 550, is greater than 0.1 μm, the plurality of alignment electrodes 525 may have different shades on a planar image of the interposer 500 captured by photolithography equipment. In this case, the photolithography equipment may not recognize the alignment key when performing the alignment operation for photolithography processes.

According to an aspect of the inventive concept, the difference between (i.e., variation range of) the thicknesses of the portions of the plurality of alignment electrodes 525, protruding from the upper surfaces 552a and 554a of the interposer protective layer 550, may be within 0.1 μm. Accordingly, during the process of fabricating the interposer 500, the alignment for the photolithography processes may be easily performed.

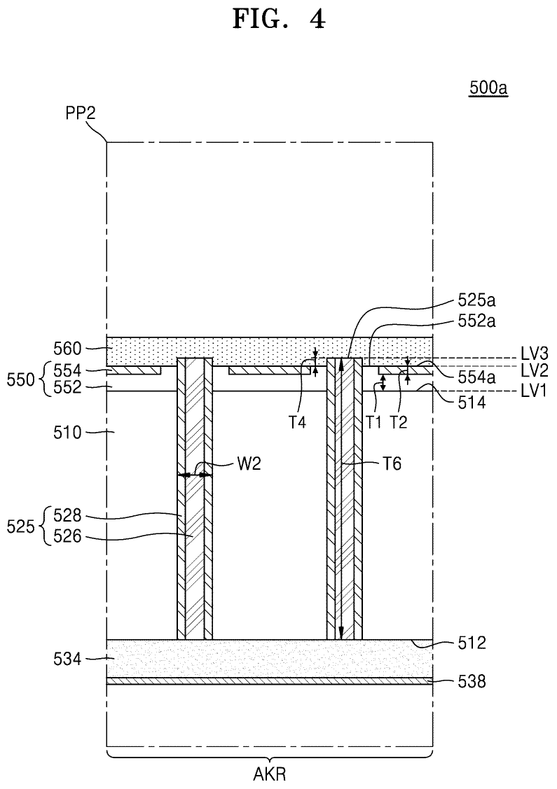

FIG. 4 is an enlarged cross-sectional view of region PP2 of FIG. 2, showing a portion of an interposer 500a according to an embodiment. Hereinafter, features described with reference to FIG. 4 may be only to describe an alignment key region AKR of the interposer 500a, unless specified otherwise. Also, the same reference numerals as in FIG. 3B are given to the same elements, and repeated descriptions thereof may be omitted.

Referring to FIG. 4, a seed layer 572 may be omitted from the alignment key region AKR of the interposer 500a. A rear wiring protective layer 560 may cover upper surfaces 552a and 554a of an interposer protective layer 550. The rear wiring protective layer 560 may directly contact and cover the upper surface and side surface of a portion of an alignment electrode 525 that protrudes from the upper surfaces 552a and 554a of the interposer protective layer 550. In other words, the recessed portion of the rear wiring protective layer 560 may cover (i.e., overlap) the upper surface of the alignment electrode 525 in a plan view, and a diameter of the recessed portion in a plan view is substantially same as the second width W2. The recessed portion of the rear wiring protective layer 560 may cover and contact the side surface of the portion of an alignment electrode 525. The lower surface of the rear wiring protective layer 560 may be covered by the interposer protective layer 550 and a portion of the alignment electrode 525.

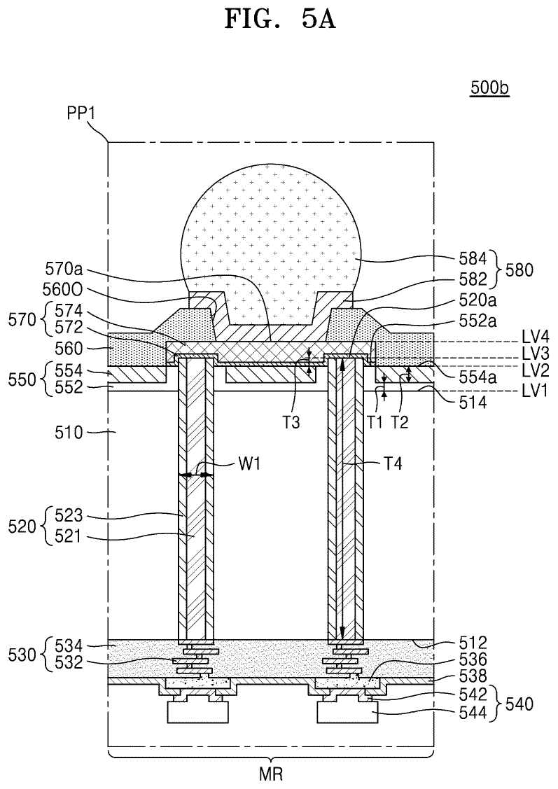

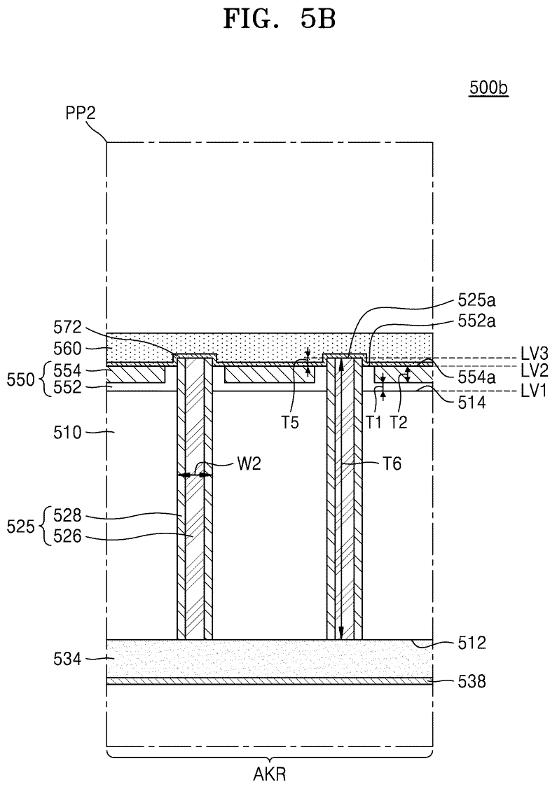

FIG. 5A is an enlarged cross-sectional view of region PP1 of FIG. 2, showing a portion of an interposer 500b according to an embodiment. FIG. 5B is an enlarged cross-sectional view of region PP2 of FIG. 2, showing a portion of the interposer 500b according to an embodiment. Hereinafter, the same reference numerals as in FIGS. 3A and 3B are given to the same elements, and repeated descriptions thereof may be omitted.

Referring to FIGS. 5A and 5B, a first thickness T1 of a lower interposer protective layer 552 of the interposer 500b may be less than a second thickness T2 of an upper interposer protective layer 554 of the interposer 500b. In other words, the second thickness T2 of the upper interposer protective layer 554 may be greater than the first thickness T1 of the lower interposer protective layer 552.

Alternatively, although not shown in the drawings, the first thickness T1 of the lower interposer protective layer 552 may be substantially the same as the second thickness T2 of the upper interposer protective layer 554. The above configurations may vary depending on the design of the interposer 500b to be fabricated.

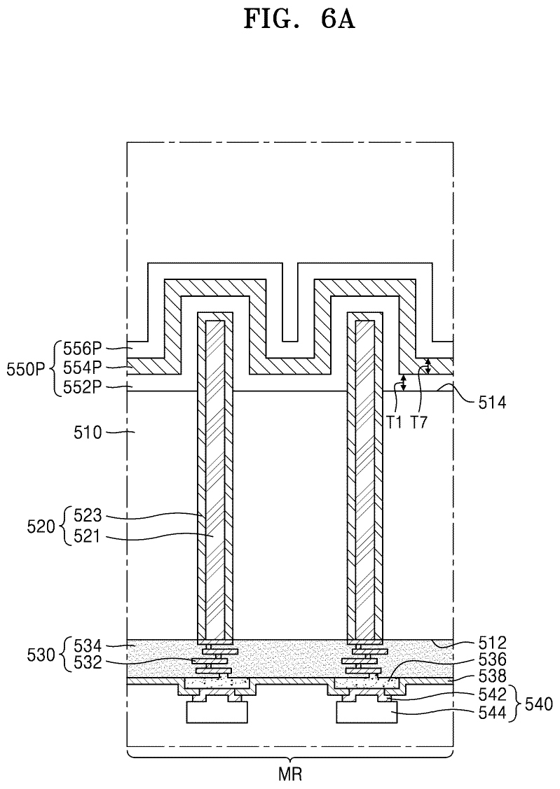

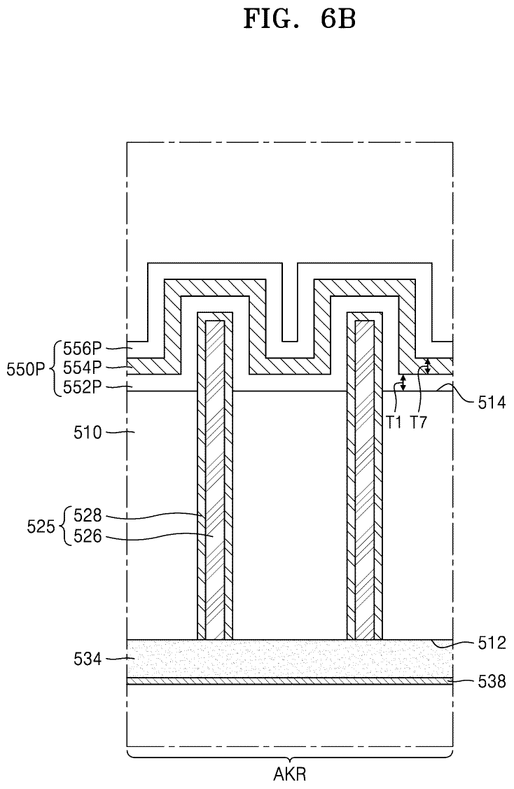

FIGS. 6A to 12B are cross-sectional views sequentially showing a method of fabricating an interposer, according to an embodiment. Specifically, FIGS. 6A to 12B are cross-sectional views sequentially showing a method of fabricating the interposer described with reference to FIGS. 1 to 3B. In particular, FIGS. 6A, 7A, 8A, 9A, 10A, 11A, and 12A are enlarged cross-sectional views of region PP1 of FIG. 2, and FIGS. 6B, 7B, 8B, 9B, 10B, 11B, and 12B are enlarged cross-sectional views of region PP2 of FIG. 2.

Referring to FIGS. 6A and 6B, a base layer 510 is prepared, and then an interposer through-electrode 520 and an alignment electrode 525 connecting a first surface 512 and a second surface 514 of the base layer 510 may be formed. The interposer through-electrode 520 may be formed in the main region MR of FIG. 1 and the alignment electrode 525 may be formed in the alignment key region AKR of FIG. 1.

Subsequently, a wiring structure 530 disposed on the first surface 512 of the base layer 510 and a bonding pad 540 disposed above the first surface 512 of the base layer 510 and electrically connected to the wiring structure 530 may be formed in the main region MR. Here, regarding the wiring structure 530 in the alignment key region AKR, only an inter-wiring insulating layer 534 may be formed. The inter-wiring insulating layer 534 may extend from the main region MR to the alignment key region AKR.

The base layer 510, on which the interposer through-electrode 520, the wiring structure 530, and the bonding pad 540 are formed, may be attached to a support substrate such that the first surface 512 of the base layer 510 faces the support substrate. The base layer 510 may be attached to the support substrate with a release adhesive film therebetween. After the base layer 510 is attached to the support substrate, a portion of the base layer 510 opposite the first surface 512 of the base layer 510 is removed. Accordingly, the interposer through-electrode 520 and the alignment electrode 525 may protrude outward from the second surface 514 of the base layer 510.

A preliminary lower interposer protective layer 552P, a preliminary upper interposer protective layer 554P, and a covering layer 556P may be sequentially formed on the second surface 514 of the base layer 510. The preliminary lower interposer protective layer 552P conformally covers the second surface 514 of the base layer 510 and the side surface and upper surface of the interposer through-electrode 520 protruding outward from the second surface 514 of the base layer 510. The preliminary lower interposer protective layer 552P may further conformally cover the side surface and upper surface of the alignment electrode 525 protruding outward from the second surface 514 of the base layer 510.

The preliminary lower interposer protective layer 552P, the preliminary upper interposer protective layer 554P, and the covering layer 556P may be collectively referred to as a preliminary interposer protective layer 550P. That is, the preliminary interposer protective layer 550P may include the preliminary lower interposer protective layer 552P, the preliminary upper interposer protective layer 554P, and the covering layer 556P. The preliminary lower interposer protective layer 552P may have a first thickness T1 and the preliminary upper interposer protective layer 554P may have a seventh thickness T7. The seventh thickness T7 of the preliminary upper interposer protective layer 554P may be greater than the second thickness T2 of the upper interposer protective layer 554 (FIGS. 3A and 3B).

The preliminary lower interposer protective layer 552P, the preliminary upper interposer protective layer 554P, and the covering layer 556P may each include an inorganic material. For example, the preliminary lower interposer protective layer 552P, the preliminary upper interposer protective layer 554P, and the covering layer 556P may each include silicon oxide, silicon nitride, and silicon oxide. Alternatively, the preliminary lower interposer protective layer 552P, the preliminary upper interposer protective layer 554P, and the covering layer 556P may each include or be formed of a PID.

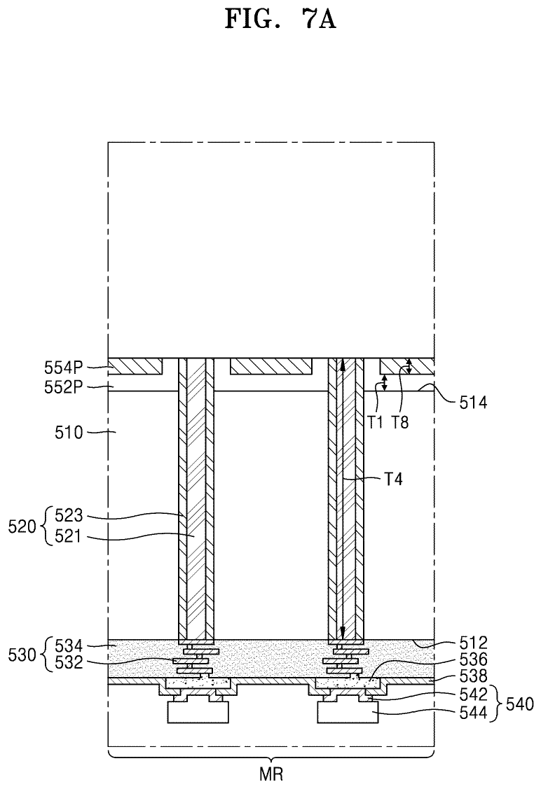

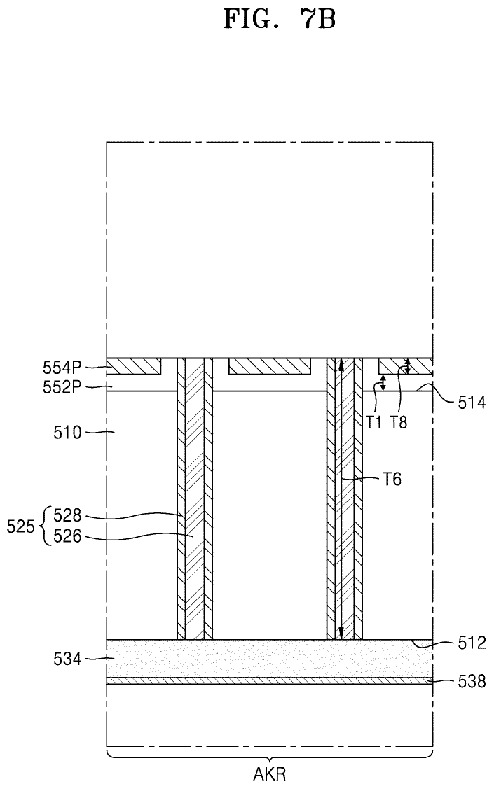

Referring to FIGS. 7A and 7B, a planarization process may be performed to remove an upper portion of each of the preliminary interposer protective layer 550P, the interposer through-electrode 520, and the alignment electrode 525, so that the covering layer 556P is completely removed and the thickness of the preliminary upper interposer protective layer 554P becomes an eighth thickness T8. The eighth thickness T8 of the preliminary upper interposer protective layer 554P may be less than the seventh thickness T7 of the preliminary upper interposer protective layer 554P (FIGS. 6A and 6B) and greater than the second thickness T2 of the upper interposer protective layer 554 (FIGS. 3A and 3B).

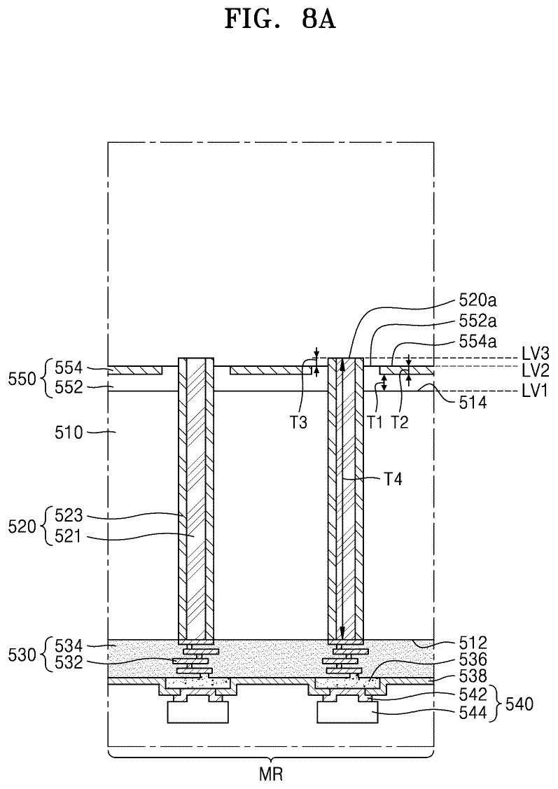

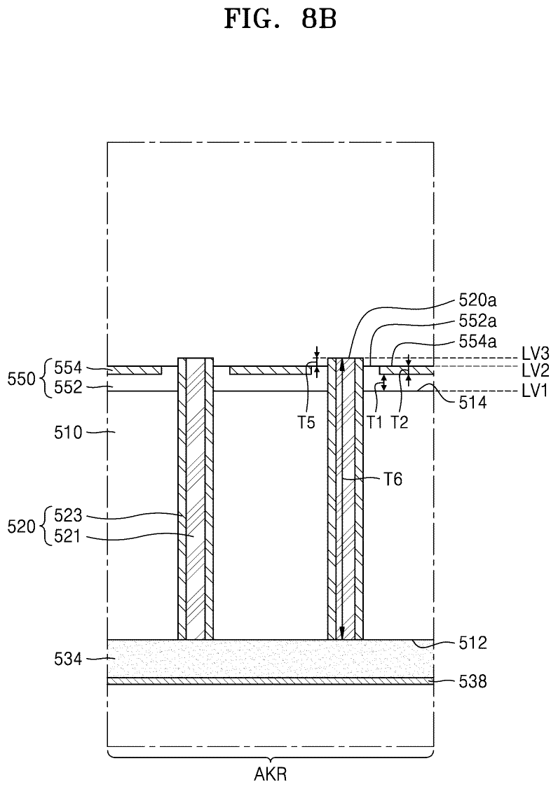

Referring to FIGS. 8A and 8B together, a dry etching process may be performed on the preliminary upper interposer protective layer 554P and the preliminary lower interposer protective layer 552P. The upper portions of the preliminary upper interposer protective layer 554P and the preliminary lower interposer protective layer 552P may be removed by the dry etching process. Accordingly, an upper interposer protective layer 554 may be formed from the preliminary upper interposer protective layer 554P and a lower interposer protective layer 552 may be formed from the preliminary lower interposer protective layer 552P. The lower interposer protective layer 552 and the upper interposer protective layer 554 may be collectively referred to as an interposer protective layer 550. Here, the interposer through-electrode 520 and the alignment electrode 525 may not be etched.

The second surface 514 of the base layer 510 may be at a first vertical level LV1. An upper surface 554a of the upper interposer protective layer 554 and an upper surface 552a of the lower interposer protective layer 552 may be at a second vertical level LV2 that is higher than the first vertical level LV1. An upper surface 520a of the interposer through-electrode 520 and an upper surface 525a of the alignment electrode 525 may be at a third vertical level LV3 that is higher than the second vertical level LV2.

As the dry etching process is performed on the preliminary upper interposer protective layer 554P and the preliminary lower interposer protective layer 552P of FIGS. 7A and 7B, the thickness of a portion of each of the plurality of alignment electrodes 525, protruding from the upper surfaces 552a and 554a of the interposer protective layer 550, may be substantially constant in a horizontal direction. The difference between the thicknesses of the portions of the plurality of alignment electrodes 525, protruding from the upper surfaces 552a and 554a of the interposer protective layer 550, may be minimized so that the variation range of the thicknesses thereof is within 0.1 μm. As the difference between the thicknesses of the portions of the plurality of alignment electrodes 525, protruding from the upper surfaces 552a and 554a of the interposer protective layer 550, is minimized, the plurality of alignment electrodes 525 may function appropriately as the alignment keys when an interposer pad 570 is formed in a subsequent process.

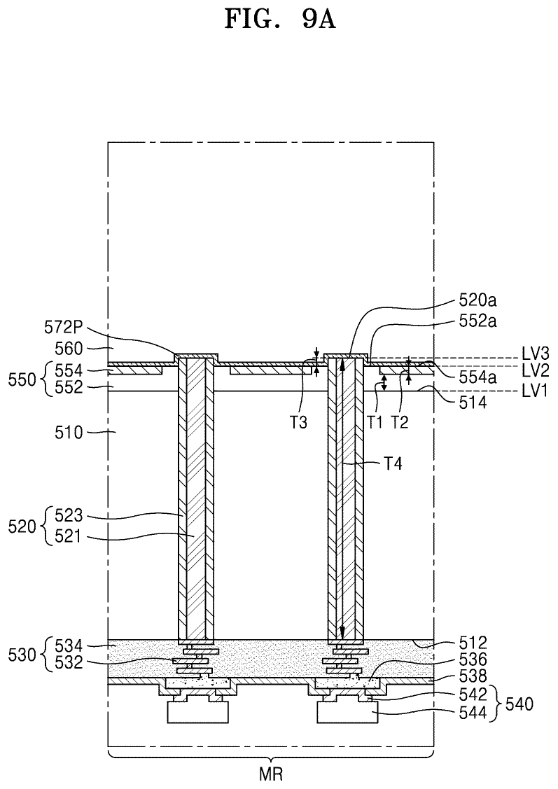

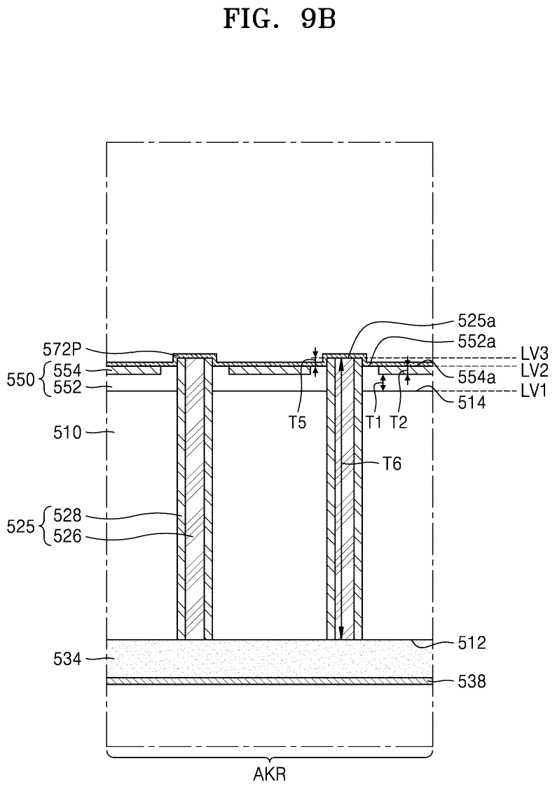

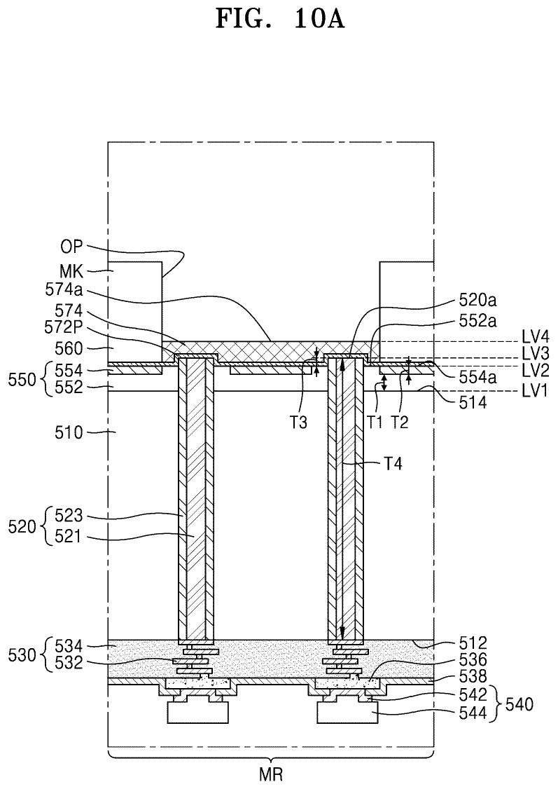

Referring to FIGS. 9A and 9B, a preliminary seed layer 572P is formed to conformally cover the exposed surfaces of the interposer protective layer 550, the interposer through-electrode 520, and the alignment electrode 525. The preliminary seed layer 572P may conformally cover the upper surfaces 552a and 554a of the interposer protective layer 550 and the upper surface 520a and side surface of the interposer through-electrode 520 and the upper surface 525a and side surface of the alignment electrode 525, which are exposed through the upper surfaces 552a and 554a of the interposer protective layer 550.

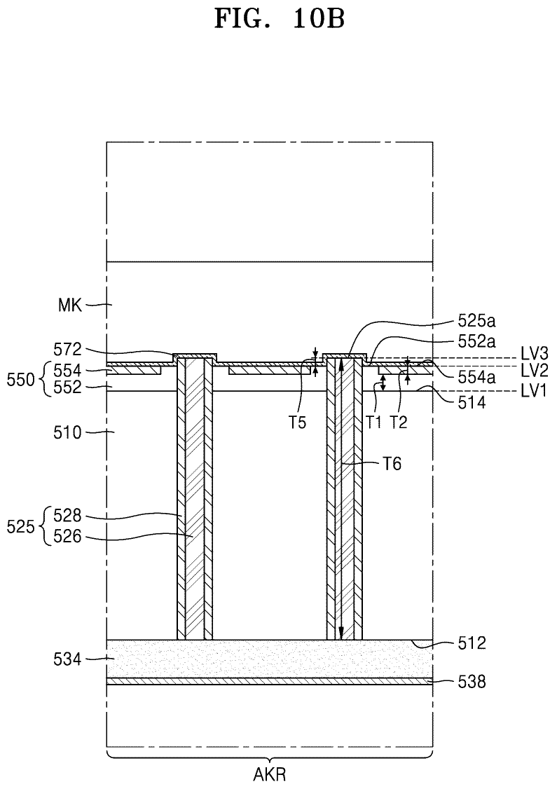

Referring to FIGS. 10A and 10B, a mask pattern MK may be formed to cover the preliminary seed layer 572P. The mask pattern MK may include an opening OP for exposing a portion of the preliminary seed layer 572P that vertically overlaps a pair of interposer through-electrodes 520 in the main region MR. In some embodiments, the opening OP for exposing a portion of the preliminary seed layer 572P that vertically overlaps one or more of interposer through-electrodes 520 in the main region MR. The opening OP may also expose another portion of the preliminary seed layer 572P in a region adjacent to the pair of interposer through-electrodes 520. The mask pattern MK may completely cover the upper surface of the preliminary seed layer 572P in the alignment key region AKR.

Subsequently, a conductive pad layer 574 may be formed on the preliminary seed layer 572P that is exposed and not covered by the mask pattern MK. The conductive pad layer 574 may be formed by a plating method using the preliminary seed layer 572P as a seed. In some embodiments, the conductive pad layer 574 may be formed by an electroplating method using the preliminary seed layer 572P as a seed. An upper surface 574a of the conductive pad layer 574 may be at a fourth vertical level LV4, which is higher than the third vertical level LV3.

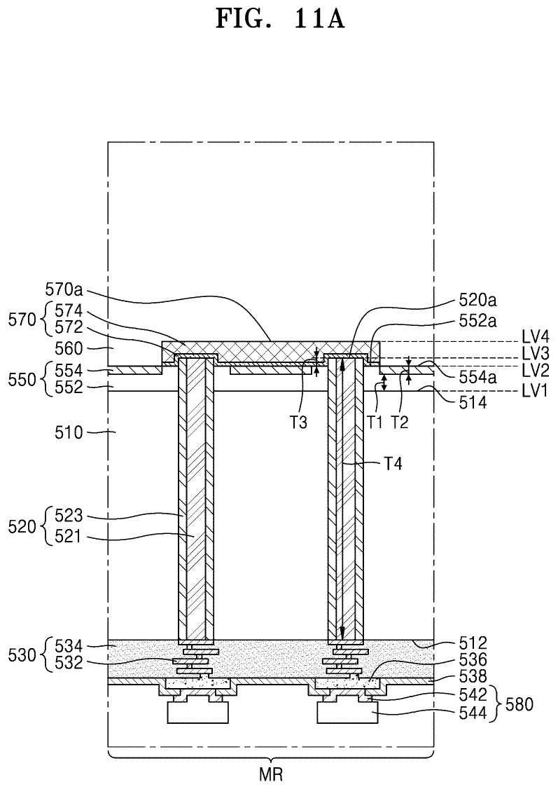

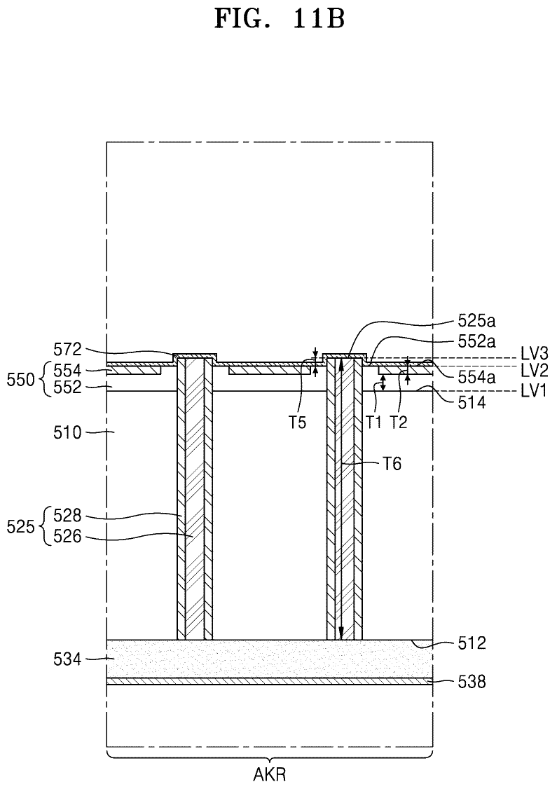

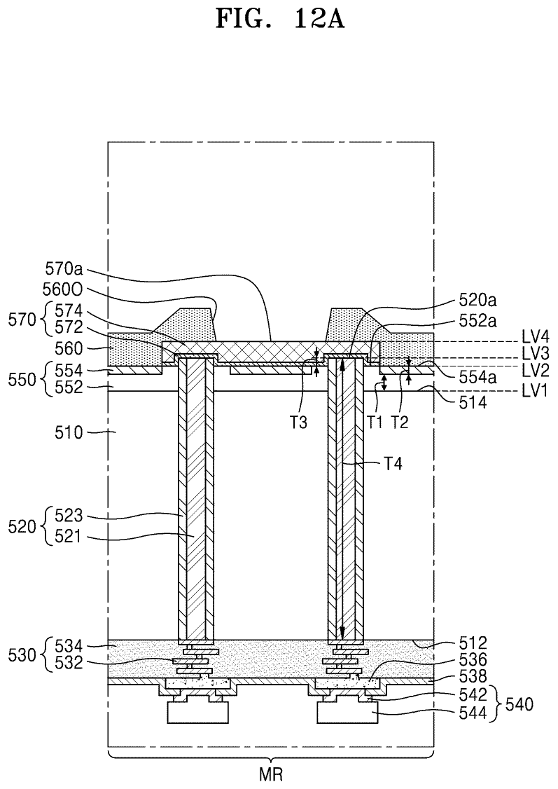

Referring to FIGS. 11A and 11B, the mask pattern MK is removed, and then a portion of the preliminary seed layer 572P, which is exposed and not covered by the conductive pad layer 574 in the main region MR, is removed. Accordingly, the interposer pad 570 including the seed layer 572 and the conductive pad layer 574 is formed. Here, the preliminary seed layer 572P may or may not be removed from the alignment key region AKR. When the preliminary seed layer 572P is not removed from the alignment key region AKR, the preliminary seed layer 572P that is not removed may be referred to as the seed layer 572.

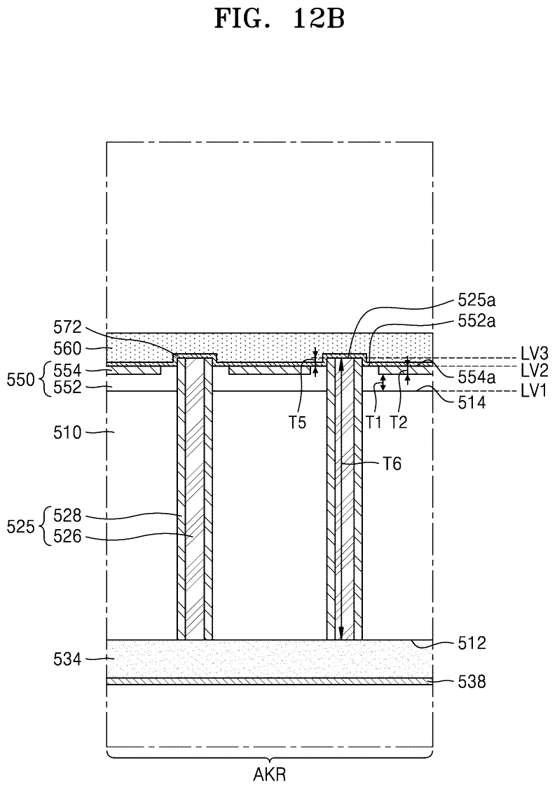

Referring to FIGS. 12A and 12B, a rear wiring protective layer 560 is formed, which has a terminal opening 5600 that exposes a portion of the interposer pad 570 and covers the remaining portion of the interposer pad 570 and the interposer protective layer 550. The rear wiring protective layer 560 may extend from the main region MR to the alignment key region AKR.

Subsequently, as shown in FIGS. 3A and 3B, an interposer connection terminal 580 is formed, which includes a rear UBM layer 582 on the interposer pad 570 and an interposer conductive cap 584 on the rear UBM layer 582 in the main region MR. As a result, the interposer 500 may be formed.

FIG. 13 is a cross-sectional view showing a semiconductor package 1000 including an interposer 500 according to embodiments.

Referring to FIG. 13, the semiconductor package 1000 may include a main board 600, on which the interposer 500 is mounted, and at least one sub-semiconductor package 10 and a third semiconductor chip 400, which are attached to the interposer 500. The at least one sub-semiconductor package 10 and the third semiconductor chip 400 may be mounted on the interposer 500 while being spaced apart from each other in the horizontal direction.

The sub-semiconductor package 10 and the third semiconductor chip 400 may be electrically connected to the interposer 500 by bonding pads 540. The at least one sub-semiconductor package 10 may have a plurality of first upper connection pads 122 and the third semiconductor chip 400 may have a plurality of second upper connection pads 420. The bonding pads 540 may be connected to the plurality of first upper connection pads 122 and the plurality of second upper connection pads 420. In some embodiments, chip connection bumps may be arranged between the bonding pads 540 and the first upper connection pads 122 and between the bonding pads 540 and the second upper connection pads 420. The bonding pads 540 and the first upper connection pads 122 may be electrically connected to each other via the chip connection bumps, and the bonding pads 540 and the second upper connection pads 420 may be electrically connected to each other via the chip connection bumps. Accordingly, each of the first and second semiconductor chips 100 and 200 may be electrically connected to the interposer 500.

The sub-semiconductor package 10 includes the first semiconductor chip 100 and a plurality of the second semiconductor chips 200. Although the sub-semiconductor package 10 is shown in FIG. 13 as including four second semiconductor chips 200, the embodiment is not limited thereto. For example, the sub-semiconductor package 10 may include at least two second semiconductor chips 200. In some embodiments, the number of second semiconductor chips 200 of the sub-semiconductor package 10 may be a multiple of 4. The plurality of second semiconductor chips 200 may be sequentially stacked on the first semiconductor chip 100 in the vertical direction. The first semiconductor chip 100 and the plurality of second semiconductor chips 200 may be sequentially stacked on each other such that active surfaces thereof are oriented downward.

The first semiconductor chip 100 may include a first semiconductor substrate 110 having an active surface on which a first semiconductor device is formed, first upper connection pads 122 and first lower connection pads 124 arranged on the active surface and inactive surface, respectively, of the first semiconductor substrate 110, and first through-electrodes 130 passing through at least a portion of the first semiconductor substrate 110 and electrically connecting the first upper connection pads 122 to the first lower connection pads 124.

The first semiconductor substrate 110 may include, for example, a semiconductor material, such as silicon (Si). Also, the first semiconductor substrate 110 may include semiconductor elements, such as germanium, or compound semiconductors, such as silicon carbide (SiC), gallium arsenide (GaAs), indium arsenide (InAs), and indium phosphide (InP). The first semiconductor substrate 110 may include a conductive region, for example, a well doped with impurities. The first semiconductor substrate 110 may have various device isolation structures, such as a shallow trench isolation (STI) structure.

As used herein, the upper surface and lower surface of a semiconductor substrate, such as the first semiconductor substrate 110, refer to the active side and inactive side of the semiconductor substrate, respectively. That is, even when the active side of the semiconductor substrate is located lower than the inactive side of the semiconductor substrate in a final product, the active side of the semiconductor substrate is referred to as the upper surface of the semiconductor substrate and the inactive side of the semiconductor substrate is referred to as the lower surface of the semiconductor substrate in this specification. In addition, the terms, such as the upper surface and lower surface, may be used for each of the components arranged on the active side and inactive side of the semiconductor substrate.

The first semiconductor device including a plurality of various types of individual devices may be formed on the active surface of the first semiconductor substrate 110.

Each of the second semiconductor chips 200 may include a second semiconductor substrate 210 having an active surface on which a second semiconductor device is formed, inner upper connection pads 222 and inner lower connection pads 224 arranged on the active surface and inactive surface, respectively, of the second semiconductor substrate 210, and second through-electrodes 230 passing through at least a portion of the second semiconductor substrate 210 and electrically connecting the inner upper connection pads 222 to the inner lower connection pads 224.

The second semiconductor substrate 210, the inner upper connection pads 222, the inner lower connection pads 224, and the second through-electrodes 230 may be substantially the same as the first semiconductor substrate 110, the first upper connection pads 122, the first lower connection pads 124, and the first through-electrodes 130. Accordingly, detailed descriptions thereof are omitted.

Also, inner connection terminals 240 may be respectively attached to the inner upper connection pads 222 of each of the plurality of second semiconductor chips 200. The inner connection terminals 240 may electrically connect the first lower connection pads 124 of the first semiconductor chip 100 to the inner upper connection pads 222 of the plurality of second semiconductor chips 200 and may electrically connect the inner lower connection pads 224 and inner upper connection pads 222 of the plurality of second semiconductor chips 200.

In some embodiments, the first semiconductor chip 100 may have a serial-parallel conversion circuit and include a buffer chip for controlling a dynamic random access memory (DRAM) semiconductor chip. In some embodiments, the second semiconductor chip 200 may include a DRAM semiconductor chip. The first semiconductor chip 100 may be referred to as a master chip, the second semiconductor chip 200 may be referred to as a slave chip, and the sub-semiconductor package 10 including the first semiconductor chip 100 and the plurality of second semiconductor chips 200 may be referred to as a high bandwidth memory (HBM) DRAM.

An insulating adhesive layer 350 may be located between the first semiconductor chip 100 and each of the plurality of second semiconductor chips 200. The insulating adhesive layer 350 may include a non-conductive film (NCF), non-conductive paste (NCP), insulating polymer, or epoxy resin. The insulating adhesive layers 350 may surround the inner connection terminals 240 and fill spaces between the first semiconductor chip 100 and the plurality of second semiconductor chips 200.

In some embodiments, a topmost one of the second semiconductor chip 200, which is located furthest from the first semiconductor chip 100 and on the uppermost layer of the sub-semiconductor package 10, may not include the inner lower connection pads 224 and the second through-electrodes 230. In some embodiments, the topmost one of the second semiconductor chip 200 may have a thickness greater than that of each of the other second semiconductor chips 200.

The width and area of the first semiconductor chip 100 may be greater than the width and area of each of the plurality of second semiconductor chips 200. The sub-semiconductor package 10 may further include a molding layer 300 that is disposed on the first semiconductor chip 100 and surrounds the side surfaces of the plurality of second semiconductor chips 200 and the side surfaces of the insulating adhesive layers 350. The molding layer 300 may include, for example, an epoxy mold compound (EMC).

The third semiconductor chip 400 may include a third semiconductor substrate 410 and second upper connection pads 420. The third semiconductor substrate 410 and the second upper connection pads 420 include components that are substantially similar to the first semiconductor substrate 110 and the first upper connection pads 122, respectively, or substantially similar to the second semiconductor substrate 210 and the inner upper connection pads 222. Accordingly, detailed descriptions thereof are omitted.

The third semiconductor chip 400 may include, for example, a central processing unit (CPU) chip, graphics processing unit (GPU) chip, or application processor (AP) chip. The interposer 500 may include a base layer 510, interposer through-electrodes 520, a wiring structure 530, bonding pads 540, an interposer protective layer 550, interposer pads 570, and a rear wiring protective layer 560. The interposer 500 may include a main region MR and alignment key regions AKR.

In some embodiments, the semiconductor package 1000 may include one of the interposers 500a and 500b described with reference to FIGS. 4 to 5B instead of the interposer 500. The interposers 500, 500a, and 500b have been described in detail with reference to FIGS. 1 to 5B, and thus, repeated descriptions thereof are omitted. The first and second semiconductor chips 100 and 200 may be disposed on the first surface 512 of the base layer 510 of the interposer 500, and may be electrically connected to a corresponding ones of the plurality of bonding pads 540. The alignment electrode 525 is electrically insulated from the interposer pad, the first and second semiconductor chips 100 and 200. The third semiconductor chip 400, which may be spaced apart from the first and second semiconductor chips 100 and 200 in a horizontal direction, may be disposed on the first surface 512 of the base layer 510 of the interposer 500. The third semiconductor chips 400 may be electrically connected to a corresponding ones of the plurality of bonding pads 540. The alignment electrode 525 is electrically insulated from the interposer pad, the third semiconductor chip 400.

A first underfill layer 380 may be located between the sub-semiconductor package 10 and the interposer 500 and a second underfill layer 480 may be located between the third semiconductor chip 400 and the interposer 500.

The semiconductor package 1000 may further include a package molding layer 900 that is disposed on the interposer 500 and surrounds side surfaces of the sub-semiconductor packages 10 and the third semiconductor chip 400. The package molding layer 900 may include, for example, an EMC.

In some embodiments, the package molding layer 900 may cover the upper surface of the interposer 500 and the side surface of each of the sub-semiconductor packages 10 and the third semiconductor chip 400 but not cover the upper surfaces of the sub-semiconductor packages 10 and the third semiconductor chip 400. The semiconductor package 1000 may further include a heat dissipation member that covers the upper surfaces of the sub-semiconductor packages 10 and the third semiconductor chip 400. The heat dissipation member may include a heat dissipation plate, such as a heat slug and heat sink. In some embodiments, the heat dissipation member may be disposed on the upper surface of the main board 600 and surround the sub-semiconductor package 10, the third semiconductor chip 400, and the interposer 500.

An interposer connection terminal 580 may be attached to each of the interposer pads 570. The interposer connection terminals 580 may electrically connect the interposer 500 and the main board 600 to each other.

The main board 600 may include a base board layer 610, board upper pads 624 and board lower pads 622 arranged on the upper surface and lower surface of the base board layer 610, respectively, and board wiring layers 630 electrically connecting the board upper pads 624 to the board lower pads 622 within the base board layer 610. In some embodiments, the main board 600 may include a printed circuit board (PCB). For example, the main board 600 may include a multi-layer PCB. The base board layer 610 may include at least one material selected from a group consisting of phenolic resin, epoxy resin, and polyimide.

A solder resist layer (not shown) may be formed on each of the upper surface and lower surface of the base board layer 610 to expose the board upper pads 624 and the board lower pads 622. An interposer connection terminal 580 may be connected to each of the board upper pads 624 and a package connection terminal 650 may be connected to each of the board lower pads 622. The package connection terminal 650 connected to the board lower pad 622 may connect the semiconductor package 1000 to the outside.

The alignment electrode 525 of the interposer 500 may include a dummy electrode. The alignment electrode 525 may be electrically insulated from the sub-semiconductor package 10, the third semiconductor chip 400, and the main board 600. The alignment electrode 525 may not have any function other than the function of the alignment key.

While the inventive concept has been particularly shown and described with reference to embodiments thereof, it will be understood that various changes in form and details may be made therein without departing from the spirit and scope of the following claims.

1. An interposer comprising:
a base layer having a first surface and a second surface opposite to each other, a main region, and an alignment key region surrounding the main region;
a composite wiring layer disposed on the first surface of the base layer and comprising a wiring conductive layer and an inter-wiring insulating layer surrounding the wiring conductive layer;
an interposer protective layer on the second surface of the base layer;
a rear wiring protective layer on an upper surface of the interposer protective layer; and
an alignment electrode located in the alignment key region passing through the base layer and the interposer protective layer, and a portion of the alignment electrode being inserted into the rear wiring protective layer,
wherein the alignment electrode is electrically insulated from the wiring conductive layer, and a vertical level of the upper surface of the interposer protective layer is constant from the main region to the alignment key region.

2. The interposer of claim 1, wherein a thickness of a portion of the alignment electrode protruding from the upper surface of the interposer protective layer is greater than 0 μm but not more than 1.5 μm.

3. The interposer of claim 1, wherein a thickness of a portion of the alignment electrode protruding from the upper surface of the interposer protective layer is about 1/30 to about 1/10 of a horizontal width of the alignment electrode.

4. The interposer of claim 1, wherein the interposer protective layer comprises:
a lower interposer protective layer and an upper interposer protective layer sequentially stacked on each other; and
a vertical level of an uppermost surface of the lower interposer protective layer is same as a vertical level of an upper surface of the upper interposer protective layer.

5. The interposer of claim 4, wherein a vertical level of an upper surface of the alignment electrode is higher than the vertical level of the upper surface of the interposer protective layer.

6. The interposer of claim 1, wherein the alignment key region comprises a corner region, and the alignment electrode is located in the corner region.

7. The interposer of claim 1, further comprising a seed layer between the rear wiring protective layer and the alignment electrode,
wherein the seed layer covers an upper surface of the alignment electrode and a side surface of a portion of the alignment electrode protruding from the upper surface of the interposer protective layer.

8. The interposer of claim 7, wherein the seed layer extends onto the upper surface of the interposer protective layer.

9. The interposer of claim 1, wherein the rear wiring protective layer is in direct contact with the alignment electrode.

10. The interposer of claim 1, wherein the interposer protective layer comprises a photo imagable dielectric material.

11. An interposer comprising:
a base layer having a first surface and a second surface opposite to each other, a main region, and an alignment key region surrounding the main region;
a composite wiring layer located in the main region and disposed on the first surface of the base layer;
an interposer protective layer covering the second surface of the base layer;
at least one interposer through-electrode located in the main region and passing through the base layer and the interposer protective layer;
at least one alignment electrode located in the alignment key region and passing through the base layer and the interposer protective layer;
an interposer pad covering a portion of the interposer through-electrode protruding from an upper surface of the interposer protective layer;
an interposer connection terminal on the interposer pad; and
a rear wiring protective layer covering a portion of the alignment electrode protruding from the upper surface of the interposer protective layer in a plan view.

12. The interposer of claim 11, wherein the interposer through-electrode and the alignment electrode are each provided in plurality,
wherein the plurality of alignment electrodes is arranged two-dimensionally in a plan view to form a first pattern,
wherein the plurality of interposer through-electrodes is arranged two-dimensionally in a plan view to form a second pattern, and
wherein the first and second patterns are different from each other.

13. The interposer of claim 11, wherein the rear wiring protective layer extends to the main region and covers at least a portion of an upper surface of the interposer pad, and
the rear wiring protective layer is spaced apart from the interposer through-electrode.

14. The interposer of claim 11, further comprising a seed layer between the rear wiring protective layer and the alignment electrode.

15. The interposer of claim 11, wherein the composite wiring layer comprises a wiring conductive layer and an inter-wiring insulating layer surrounding the wiring conductive layer, and the inter-wiring insulating layer extends to the alignment key region.

16. The interposer of claim 11, further comprising a bonding pad, wherein the composite wiring layer comprises a wiring conductive layer and an inter-wiring insulating layer surrounding the wiring conductive layer, and the bonding pad is disposed below the wiring conductive layer in the main region.

17. The interposer of claim 11, wherein the interposer protective layer comprises a lower interposer protective layer and an upper interposer protective layer, which are sequentially stacked on each other, and a thickness of the lower interposer protective layer is greater than a thickness of the upper interposer protective layer.

18. The interposer of claim 11, wherein a vertical level of an upper surface of the interposer through-electrode is same as a vertical level of an upper surface of the alignment electrode.

19. A semiconductor package comprising:
an interposer comprising:
a base layer having a first surface and a second surface opposite to each other, a main region, and an alignment key region surrounding the main region;
a wiring conductive layer on the first surface of the base layer;
a plurality of bonding pads arranged in the main region and connected to the wiring conductive layer;
a rear wiring protective layer above the second surface of the base layer;
an interposer protective layer between the base layer and the rear wiring protective layer;
at least one interposer through-electrode located in the main region and passing through the base layer and the interposer protective layer;
at least one alignment electrode located in the alignment key region passing through the base layer and the interposer protective layer, and a portion of the alignment electrode being inserted into the rear wiring protective layer; and
an interposer pad between the interposer through-electrode and the rear wiring protective layer;
a first semiconductor chip disposed on the first surface of the base layer, electrically connected to corresponding ones of the plurality of bonding pads; and
a second semiconductor chip spaced apart from the first semiconductor chip in a horizontal direction and disposed on the first surface of the base layer and electrically connected to corresponding ones of the plurality of bonding pads,
wherein the alignment electrode is electrically insulated from the interposer pad, the first semiconductor chip and the second semiconductor chip.

20. The semiconductor package of claim 19, wherein the interposer through-electrode and the alignment electrode are each provided in plurality,
wherein the plurality of alignment electrodes is arranged two-dimensionally in a plan view to form a first pattern,
wherein the plurality of interposer through-electrodes is arranged two-dimensionally in a plan view to form a second pattern, and
wherein the first and second patterns are different from each other.

21. (canceled)
